(19) United States
(12) Patent Application Publication
(10) Pub. No.: US 2026/0125800 A1
(43) Pub. Date: May 7, 2026

(54) COATING METHOD FOR SEMICONDUCTOR EQUIPMENT

(71) Applicant: KOMICO LTD., Anseong-si, Gyeonggi-do (KR)

(72) Inventors: Jeong Geun PARK, Anseong-si, Gyeonggi-do (KR); Byeong Seon LEE, Anseong-si, Gyeonggi-do (KR); Yong Soo LEE, Anseong-si, Gyeonggi-do (KR)

(21) Appl. No.: 19/117,634

(22) PCT Filed: Nov. 14, 2023
(86) PCT No.: PCT/KR2023/018261

§ 371 Date: Apr. 2, 2025

(30) Foreign Application Priority Data
Nov. 30, 2022 (KR) 10-2022-0164053

(51) Int. Cl. C23C 24/10; B33Y 30/00; H01J 37/32

(52) U.S. Cl. CPC C23C 24/106; H01J 37/32477; B33Y 30/00

(57) ABSTRACT

A semiconductor equipment coating method according to the present disclosure includes: (a) providing, as a coating material, metal powder of a same composition as a base material; (b) forming a textured coating layer by melting the metal powder, which is the coating material, using a laser beam with an intensity of 300 to 1000 W, wherein a separation distance between an end of a laser device where the laser beam is irradiated and a coating target surface of the substrate is 8 to 20 mm, and the strength of the textured coating layer may be almost the same as the strength of the base material.

### TECHNICAL FIELD

The present disclosure relates to a coating method for semiconductor equipment, and more specifically, to a method of manufacturing a coating film applied to semiconductor equipment using physical vapor deposition (PVD).

### BACKGROUND ART

The surface treatment for semiconductor equipment used in physical vapor deposition (PVD) processes primarily employs the arc thermal spray coating method.

The arc thermal spray coating method involves supplying metal wire, melting the same through arc discharge, and then spray-depositing the same onto the surface of target objects such as chambers to form a coating. Conventionally, aluminum (AI) wire is mainly used as the metal wire, which is a material for thermal spray, and either two aluminum (Al) wires or wires of different metal types are supplied to enable melting by arc discharge.

However, with technological advancements in semiconductor equipment such as PVD, there is a trend of changing conditions and states of devices and gases. These changing conditions and states within the reaction chamber due to technological advancements serve as critical variables for coating quality management. The conventional arc thermal spray method using metal wires cannot respond to these changes in device and gas conditions, resulting in arc fluctuations and asymmetric melting, which inevitably creates adverse conditions within the reaction chamber during PVD processes. Additionally, this leads to reduced adhesion strength for capturing deposition particles (thin film materials) dispersed onto the inner walls of the reaction chamber, causing easy delamination issues and exacerbating contamination and defects in the thin films deposited on one side. Ultimately, this causes problems that reduce the efficiency of PVD process operations.

In particular, the conventional arc thermal spray coating method has the disadvantage of high porosity within the formed coating layer. This porosity causes outgassing problems during processing, resulting in longer backup times, and the surface characteristics of the formed coating layer contain numerous particle sources, reducing overall process yield.

As prior art, Korean Registered Patent Publication No. 10-0322416 disclosed a technology for manufacturing a focus ring with a textured surface that can control and stabilize the formation of impurity coatings in focus ring devices used in plasma etching equipment and processes. Additionally, Korean Patent Publication No. 2013-0044170 confirmed that components of plasma processing chambers manufactured with scratch patterns of 1 to 2 micrometers provide reduced particle contamination of wafers processed in the chamber.

Accordingly, there is a demand for technology development that can reduce particle sources, decrease porosity, and thereby increase process yield while effectively adhering process by-products to improve coating quality of products.

Therefore, after continued research into coating methods that produce coating layers with patterns that not only improve density and porosity, but also effectively adhere to the by-products of the physical vapor deposition process, the present disclosure was developed.

### DISCLOSURE OF INVENTION

### Technical Problem

The main objective of the present disclosure is to provide a method of manufacturing a coating film that has excellent bonding strength and mechanical strength, enables the formation of a high-density compact thin film, and exhibits superior adhesion of by-products generated during physical vapor deposition processes.

The present disclosure is to provide a component with a coating film formed thereon using the method of manufacturing a coating film, which has excellent adhesion of process by-products and can produce products with superior quality during physical vapor deposition processes.

### Technical Solution

To achieve the above objectives, an embodiment of the present disclosure provides a semiconductor equipment coating method in which a coating layer is formed on a coating target surface of a substrate constituting semiconductor equipment, including: (a) providing, as a coating material, metal powder of a same composition as a base material; (b) forming a textured coating layer by melting the metal powder, which is the coating material, using a laser beam with an intensity of 300 to 1000 W, wherein a separation distance between an end of a laser device where the laser beam is irradiated and a coating target surface of the substrate is 8 to 20 mm, and the ratio of the strength of the textured coating layer to the strength of the base material is 0.98 to 1.02.

In an embodiment of the present disclosure, the speed of a transport gas supplying the coating material may be 1 to 20 l/min, and the speed of a nozzle gas may be 1 to 30 l/min.

In an embodiment of the present disclosure, the diameter of the laser beam may be 0.8 to 1.5 mm.

In an embodiment of the present disclosure, the scanning speed of the laser beam may be 8 to 12 m/min.

In an embodiment of the present disclosure, the porosity of the textured coating layer may be 0.1% or less.

In an embodiment of the present disclosure, the pattern of the textured coating layer may be any one selected from a Lattice, a Circle Loop, a Honeycomb Loop, and a Wave Loop.

In an embodiment of the present disclosure, the laser beam may be provided from any one selected from a CO2 laser, a Nd:YAG (Rod/Disk) laser, a diode laser, and a fiber laser.

In an embodiment of the present disclosure, the laser beam may be provided in a directed energy deposition (DED) manner using 3D printing equipment.

In an embodiment of the present disclosure, semiconductor equipment to which the coating can be applied may be any one group selected from One piece shield, Cove ring, Shutter Disk, Depo Ring, Combined Shield, Upper Shield, Lower shield, Inner Shield, Earth shield, Platen Ring, Insulator, Plate Tag Shield URP, Plate Tag Shield LOW, SHIELD MASK, SHIELD MASK BASE, SHIELD CHAMBER UPPER, SHIELD SHUTTER UPPER, SHIELD SHUTTER LOWER.

In an embodiment of the present disclosure, the present disclosure provides a member manufactured by the manufacturing method.

### Advantageous Effects

According to the present disclosure, by performing a coating method that uses metal powder and, in addition, semiconductor application coating equipment such as 3D coating equipment that emits a laser beam, a high-density coating layer can be formed on a coating target surface on a substrate compared to a conventional arc spray coating method, and a coating film with significantly reduced porosity can be formed.

In addition, a coating film manufactured according to the present disclosure has a textured coating layer formed with a metal component having the same composition as that of a base material, so that the adhesion between the base material and the textured coating layer is excellent, and the strength of the textured coating layer exhibits the same strength as that of the base material.

In addition, a semiconductor manufacturing device coated with a coating film manufactured according to the present disclosure has a surface area that is increased compared to a base material due to the formation of a textured coating layer of various shapes, so that by-products generated during a physical vapor deposition process are effectively attached to the textured coating layer, thereby producing a semiconductor product of superior quality.

### DESCRIPTION OF DRAWINGS

FIG. 1 shows an example of a pattern that can be manufactured by a coating method for semiconductor equipment of the present disclosure.

FIG. 2 shows a photograph and a result of measuring the specific surface area of a coating layer formed by a coating method for semiconductor equipment according to Examples 1 and 2 of the present disclosure.

FIGS. 3 and 4 show scanning electron microscope (SEM) photographs of a coating layer formed by a coating method for semiconductor equipment according to Example 1 of the present disclosure.

FIG. 5 shows the results of measuring the width and thickness of each of the coating patterns formed in Examples 9 to 13, and flatness of the base material.

### BEST MODE

Unless defined otherwise, all technical and scientific terms used herein have the same meaning as commonly understood by one of ordinary skill in the art to which this disclosure belongs. In general, the nomenclature used herein is well known and commonly used in the art.

Throughout this specification, when a certain part is described as “including” a certain component, unless specifically stated otherwise, it means that it may include other components rather than excluding other components.

An aspect of the present disclosure provides a coating method for a semiconductor equipment, wherein the coating method is provided for forming a coating layer on a coating target surface of a substrate constituting the semiconductor equipment.

The semiconductor equipment coating method according to the present disclosure is for forming a coating layer on a coating target surface of a substrate constituting semiconductor equipment used in semiconductor manufacturing, using metal powder as a coating material. This method incorporates a coating technique utilizing semiconductor application coating equipment such as 3D printing equipment using a laser beam, enabling the performance of coating operations.

Specifically, a coating method for semiconductor equipment according to the present disclosure includes: (a) providing, as a coating material, metal powder of a same composition as a base material; (b) forming a textured coating layer by melting the metal powder, which is the coating material, using a laser beam with an intensity of 300 to 1000 W, wherein a separation distance between an end of a laser device where the laser beam is irradiated and a coating target surface of the substrate is 8 to 20 mm, and the strength of the textured coating layer may be almost the same as the strength of the base material.

The almost same range refers to a ratio of the strength of the textured coating layer to the strength of the base material in a range of 0.98 to 1.02.

First, metal powder having the same composition as the base material is prepared as a coating material [step (a)].

The coating material may be powder-type metal powder having a particle size of 40 to 180 μm or 44 to 150 μm.

In this regard, when using particles having the size of less than 40 μm for the metal powder, the particle size is small, which may cause vaporization or a reduced film formation rate, and when using particles having the size of more than 180 μm for the metal powder, the energy source for coating needs to be increased, and as the energy source is increased, relatively small particles within the particle size range of the coating material may cause the same problems as particles having the size of less than 40 μm.

Next, the metal powder is melted using a laser beam to form a textured coating layer using the melted metal powder on the coating target surface [step (b)].

At this time, semiconductor application coating equipment may use a directed energy deposition (DED) type of 3D printing equipment.

The 3D printing equipment may include a laser device, a focusing lens, a powder injection nozzle, and a shielding gas inlet.

The laser device may have the function of generating a laser beam internally and irradiating the generated laser beam forward.

In this regard, in the coating operation, the distance of the molten metal powder between the end of the 3D printing equipment and the coating target surface of the base material may be maintained in the range of 8 to 20 mm, thereby securing excellent mechanical properties and reducing particle generation, thereby increasing the overall coating efficiency.

When the distance between the end of the 3D printing equipment and the coating target surface of the base material is less than 8 mm, the coating may be uneven and interference between the end of the 3D printing equipment and the base material may cause problems. In addition, when the distance between the end of the 3D printing equipment and the coating target surface of the base material exceeds 20 mm, the film formation rate may be reduced.

The speed of the transport gas supplying the metal powder as a coating material may be 1 to 20 l/min, and the speed of the nozzle gas through which the coating material is sprayed may be 1 to 30 l/min. The speed of the transport gas may be 4 to 20 l/min, and the speed of the nozzle gas through which the coating material is sprayed may be 7 to 20 l/min.

In some embodiments, the laser device may include one selected from a CO2 laser, a Nd:YAG (Rod/Disk) laser, a diode laser, and a fiber laser.

In some embodiments, the laser beam irradiated from the laser device may be supplied with a power in the range of 300 to 1000 W, and also that the diameter of the laser beam may be 0.8 to 1.5 mm.

In this regard, when the intensity of the laser beam is less than 300 W or the diameter of the laser beam is less than 0.8 mm, the amount of molten metal powder is insufficient, making it difficult to form a coating layer with a uniform pattern. In addition, when the intensity of the laser beam is more than 1000 W or the diameter of the laser beam is more than 1.5 mm, the amount of molten metal powder may be sprayed in excessive amounts, causing the pattern of the coating layer to become smudged.

In some embodiments, the scanning speed of the laser beam may be 8 to 12 m/min.

When the scanning speed of the laser beam is less than 8 m/min, the amount of molten metal powder may be excessively sprayed, causing the pattern of the coating layer to become aggregated. When the scanning speed of the laser beam exceeds 12 m/min, the amount of molten metal powder is insufficient, making it difficult to form a coating layer with a uniform pattern.

By injecting the coating material prepared as the metal powder onto the coating target surface of the base material according to the metal flow using 3D printing equipment, a laser beam melts the metal powder and simultaneously forms a molten pool on the coating target surface of the base material, thereby forming a coating layer of the molten metal powder on the coating target surface of the base material.

In addition, by using the above 3D printing equipment, not only can a coating layer of a desired shape be formed, but the coating layer can also be formed in multiple layers of two or more layers to increase the specific surface area of the coating layer to a desired value or more.

In the coating operation, a molten pool is formed on the coating target surface on the base material, but almost no pores are formed at the boundary between the coating layer and the base material, and the adhesion between the coating layer and the base material is excellent.

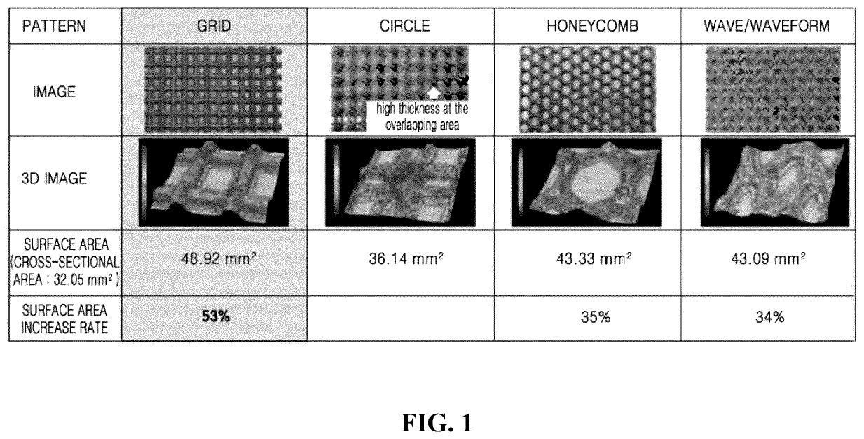

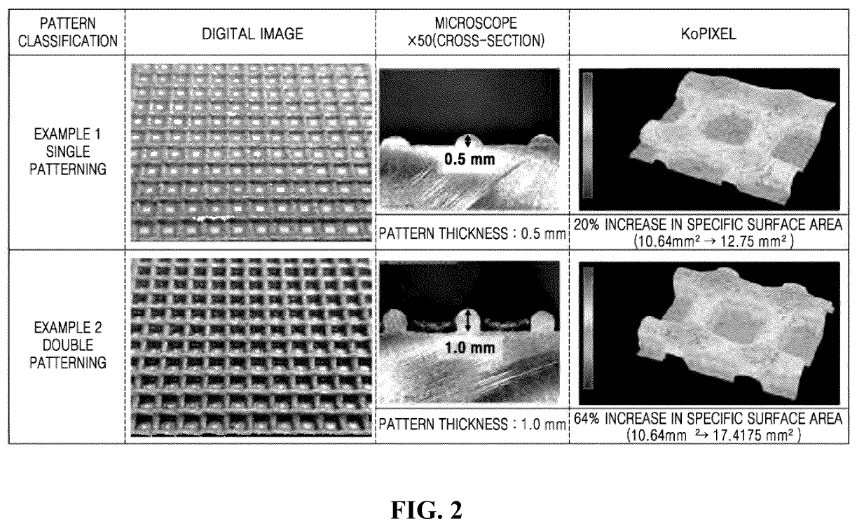

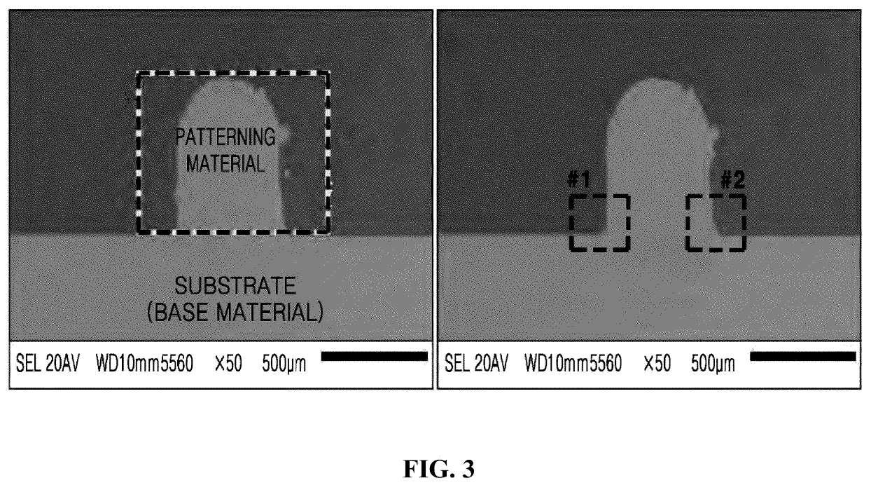

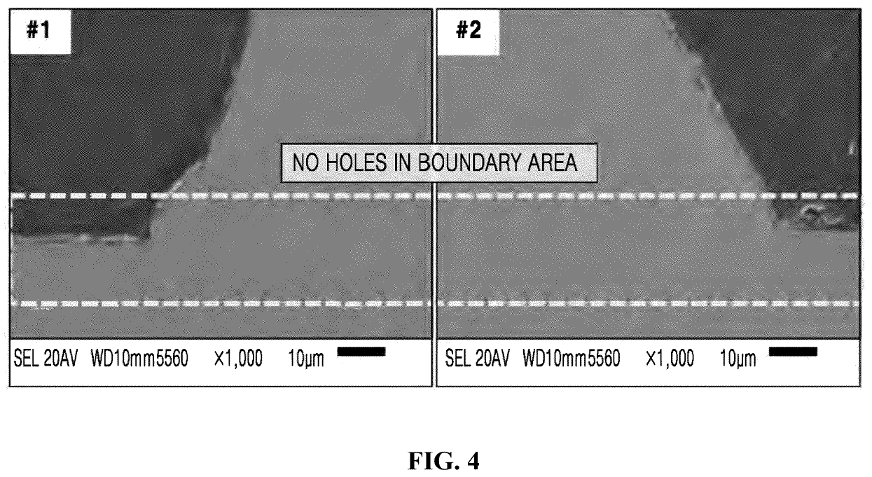

Using the 3D printing equipment, metal powder can be melted in a short period of time to form a coating layer of a desired shape. In some embodiments, as illustrated in FIG. 1 below, a coating layer having various shapes such as a lattice, a circle loop, a honeycomb loop, and a wave loop structure may be formed.

The coating method using the metal powder according to the present disclosure may be applied to all semiconductor equipment for a semiconductor deposition process, including a One piece shield, a Cove ring, a Shutter Disk, a Depo Ring, a Combined Shield, an Upper Shield, a Lower shield, an Inner Shield, an Earth shield, a Platen Ring, an Insulator, a Plate Tag Shield URP, a Plate Tag Shield LOW, SHIELD MASK, SHIELD MASK BASE, SHIELD CHAMBER UPPER, SHIELD SHUTTER UPPER, SHIELD SHUTTER LOWER, etc.

Hereinafter, the present disclosure will be described in more detail through examples. However, the following examples are only intended to illustrate the present disclosure, and the present disclosure is not limited to the following examples.

### Example 1 and Example 2

A lattice pattern coating layer was formed using a laser beam under the process conditions described in Table 1 below using SUS316L metal powder particles on SUS304 base material, and the cycle of pattern formations was performed once and twice, for each test.

In Example 1, a single metal pattern was deposited, and accordingly, the specific surface area was increased by about 20% compared to the base material. Additionally, in Example 2, a metal pattern was deposited twice, and it was confirmed that the specific surface area was increased by about 64% compared to the base material.

TABLE 1

| | | Powder | Gas (Carrier - | Nozzle | Scan |
|---|---|---|---|---|---|
| Diameter | Power | Mass | Nozzle) | distance | speed |
| 1,000 μm | 300 W | 8.0 g/min | 20 l/min | 12 mm | 1 m/min |

The Vickers strength of each of the coating layers manufactured in Examples 1 and 2 and the base material on which the coating layers were formed was measured. As a result, it was confirmed that the pattern of the coating layer manufactured by the coating method of the present disclosure exhibited a strength in a range almost 5 identical to that of the base material.

TABLE 2

| Load | | | 0.025 kgf | 0.05 kgf |
|---|---|---|---|---|
| Measurement | Pattern | Once | 268 | 258 |
| area | | Twice | 291 | 269 |
| | | Three times | 283 | 258 |
| | | Four times | 278 | 273 |
| | | Five times | 282 | 261 |
| | | Avg. | 280 | 264 |
| | Base | Once | 295 | 271 |
| | material | Twice | 284 | 264 |
| | | Three times | 270 | 276 |
| | | Four times | 268 | 255 |
| | | Five times | 293 | 263 |
| | | Avg. | 282 | 266 |

### Example 3 and Example 4

A lattice pattern coating layer was formed using a laser beam under the process conditions described in Table 1 below using SUS304 metal powder particles on SUS304 base material, and the cycle of pattern formations was performed once and twice, for each test.

The Vickers strength of each of the coating layers manufactured in Examples 3 and 4 and the base material on which the coating layers were formed was measured.

TABLE 3

| Load | | | 0.025 kgf | 0.05 kgf |
|---|---|---|---|---|
| Measurement | Pattern | Once | 288 | 251 |
| area | | Twice | 274 | 262 |
| | | Three times | 274 | 252 |
| | | Four times | 283 | 257 |
| | | Five times | 267 | 250 |
| | | Avg. | 277 | 254 |
| | Base | Once | 267 | 264 |
| | material | Twice | 273 | 254 |
| | | Three times | 272 | 254 |
| | | Four times | 277 | 251 |
| | | Five times | 282 | 271 |
| | | Avg. | 274 | 259 |

### Examples 5 and 6

A lattice pattern coating layer was formed using a laser beam under the process conditions described in Table 1 below using SUS304 metal powder particles on SUS316L base material, and the cycle of pattern formations was performed once and twice, for each test.

The Vickers strength of each of the coating layers manufactured in Examples 5 and 6 and the base material on which the coating layers were formed was measured.

TABLE 4

| Load | | | 0.025 kgf | 0.05 kgf |
|---|---|---|---|---|
| Measurement | Pattern | Once | 289 | 262 |
| area | | Twice | 283 | 259 |
| | | Three times | 278 | 253 |
| | | Four times | 275 | 263 |
| | | Five times | 270 | 275 |
| | | Avg. | 279 | 262 |
| | Base | Once | 267 | 259 |
| | material | Twice | 265 | 255 |
| | | Three times | 282 | 264 |
| | | Four times | 266 | 274 |
| | | Five times | 273 | 272 |
| | | Avg. | 271 | 265 |

### Examples 7 and 8

A lattice pattern coating layer was formed using a laser beam under the process conditions described in Table 1 below using SUS316L metal powder particles on SUS316L base material, and the cycle of pattern formations was performed once 5 and twice, for each test.

The Vickers strength of each of the coating layers manufactured in Examples 7 and 8 and the base material on which the coating layers were formed was measured.

TABLE 5

| Load | | | 0.025 kgf | 0.05 kgf |
|---|---|---|---|---|
| Measurement | Pattern | Once | 280 | 254 |
| area | | Twice | 295 | 259 |
| | | Three times | 282 | 274 |
| | | Four times | 273 | 261 |
| | | Five times | 274 | 271 |
| | | Avg. | 281 | 264 |
| | Base | Once | 278 | 266 |
| | material | Twice | 276 | 269 |
| | | Three times | 267 | 252 |
| | | Four times | 270 | 271 |
| | | Five times | 282 | 264 |
| | | Avg. | 275 | 264 |

At this time, in Examples 1 to 8, the same process parameters were used regardless of the type of stainless steel base material and powder, and it was confirmed that there was little difference in the coating properties according to type of steel.

### Examples 9 to 13

A lattice pattern coating layer was formed using a laser beam under the process conditions described in Table 6 below using SUS316L metal powder particles on SUS304 base material, and the metal pattern was formed at scan speeds of 2, 4, 6, 8, and 10 m/min.

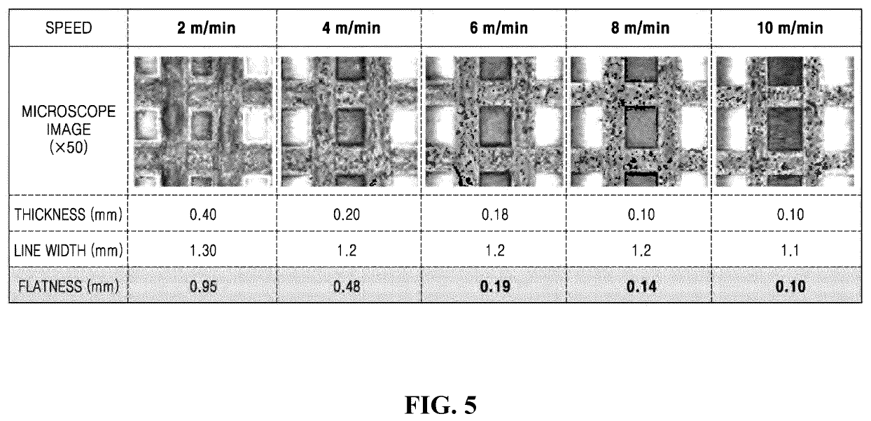

The results of measuring the width, thickness of the base material of the coating pattern formed in Examples 9 to 13 and the flatness of the base material are shown in FIG. 5. As a result, it was confirmed that when the speed of the laser beam is too low, the laser melt pool is formed at one point for a long time, which not only increases the width and thickness of the pattern, but also deforms the base material on which the metal pattern is formed, increasing the flatness of the base material.

TABLE 6

| | | Powder | Gas (Carrier - | Nozzle |
|---|---|---|---|---|
| Diameter | Power | Mass | Nozzle) | distance |
| 1200 μm | 990 W | 8 g/min | 20-10 l/min | 12 mm |

1. A semiconductor equipment coating method in which a coating layer is formed on a coating target surface of a substrate constituting semiconductor equipment, comprising:
(a) preparing metal powder having a same composition as the base material; and
(b) forming a textured coating layer by melting the metal powder, which is the coating material, using a laser beam having an intensity of 300 to 1000 W,
wherein a separation distance between an end of a laser device where a laser beam is irradiated and the coating target surface of the substrate is 8 to 20 mm, and a ratio of the strength of the textured coating layer to the strength of the base material is 0.98 to 1.02.

2. The semiconductor equipment coating method of claim 1, wherein a speed of transport gas supplying the coating material is 1 to 20 l/min, and a speed of nozzle gas is 1 to 30 l/min.

3. The semiconductor equipment coating method of claim 1, wherein a diameter of the laser beam is 0.8 to 1.5 mm.

4. The semiconductor equipment coating method of claim 1, wherein a scanning speed of the laser beam is 8 to 12 m/min.

5. The semiconductor equipment coating method of claim 1, wherein a porosity of the textured coating layer is 0.1% or less.

6. The semiconductor equipment coating method of claim 1, wherein the pattern of the textured coating layer is any one selected from a lattice, a circle loop, a honeycomb loop, and a wave loop.

7. The semiconductor equipment coating method of claim 1, wherein the laser beam is provided from any one selected from a CO2 laser, a Nd:YAG (Rod/Disk) laser, a diode laser, and a fiber laser.

8. The semiconductor equipment coating method of claim 1, wherein the laser beam is provided using a directed energy deposition (DED) method using 3D printing equipment.

9. The semiconductor equipment coating method of claim 1, wherein semiconductor equipment to which coating is applicable is any one group selected from One piece shield, Cove ring, Shutter Disk, Depo Ring, Combined Shield, Upper Shield, Lower shield, Inner Shield, Earth shield, Platen Ring, Insulator, Plate Tag Shield URP, Plate Tag Shield LOW, SHIELD MASK, SHIELD MASK BASE, SHIELD CHAMBER UPPER, SHIELD SHUTTER UPPER, and SHIELD SHUTTER LOWER.

10. A member manufactured by using the coating method of claim 1.
